(19) United States
(12) Patent Application Publication
(10) Pub. No.: US 2007/0242716 A1
(43) Pub. Date: Oct. 18, 2007

(54) High Power Vcsels With Transverse Mode Control

(75) Inventors: Nigamananda Samal, Tempe, AZ (US); Shane Johnson, Chandler, AZ (US); Yong-Hang Zhang, Scottsdale, AZ (US)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Arizona Board of Regents, a body Corporation acting on behalf of Arizona State University

(21) Appl. No.: 10/592,999

(22) PCT Filed: Mar. 21, 2005
(86) PCT No.: PCT/US05/09478

§ 371 Date: May 11, 2007

Related U.S. Application Data
(60) Provisional application No. 60/554,865, filed on Mar. 19, 2004.

(51) Int. Cl. H01S 5/183

(52) U.S. Cl. 372/46.01

(57) ABSTRACT

A single mode high power laser device such as a VCSEL is formed with two oxide apertures, one on each side of the active region or cavity. The sizes of the apertures and the distances from the apertures to the cavity center are chosen or optimum, near-Gaussian current density distribution. The high power of a VCSEL thus formed is improved still more by good heat removal by either formation of a via through the substrate and gold plating on top and bottom of the VCSEL (including the via) or by lifting the VCSEL structure from the substrate and locating it on a heat sink.

### CROSS REFERENCE TO RELATED APPLICATIONS

This application claims priority from U.S. provisional application Ser. No. 60/554,865 filed Mar. 19, 2004, entitled “Single Mode High Power VCSELs in the names of Nigamananda Samal, Yong-Hang Zhang and Shane Johnson. That application is incorporated herein by reference.

### BACKGROUND

VCSEL, or Vertical Cavity Surface Emitting Laser, is a semiconductor micro-laser diode that emits light in a cylindrical beam vertically from the surface of a fabricated wafer and offers significant advantages when compared to the edge-emitting lasers currently used in the majority of fiber optical communication systems. When compared with edge-emitters, VCSELs offer lower threshold currents, low-divergence circular output beams, higher direct modulation speed, longitudinal single mode emission, case of integration to form 2-D arrays and higher coupling efficiency into optical fiber. However, high fiber-coupling efficiencies are only reached at low optical powers, because with increasing output power higher order transverse modes are supported by the cavity. In general, the complex transverse modal behavior of VCSELs at high pump rates is a major drawback for many practical applications. The modal behavior, just like most of the other key properties of the VCSELs, depends strongly on the confinement mechanism. Despite many of their inherent advantages over their rivals, VCSELs still suffer from many inadequacies. Most prominent are “limited power” and lack of “modal purity.” These unresolved issues have compelled the VCSEL to enjoy only a 10% share of the whole semiconductor laser market.

Typical applications include optical data links, proximity sensors, encoders, laser range finders, laser printing, bar code scanning and, last but surely not the least, optical storage.

Different Effects in the Cavity Influencing the Modal Behavior of the Laser

Multi Mode Behavior Due to Inhomogeneous Spatial Gain Distribution:

The distinction between the influence of different effects such as pump induced current spreading, spatial hole burning and thermal gradients inside the cavity on the carrier distribution have been discussed by Degen et al. [1]. These complex and partly counter-acting effects tend to produce high order transverse modes in the optical cavity. The pump-induced inhomogeneities predominantly govern the carrier distribution in the laser [1]. These inhomogeneities arise purely from the current flow through the confinement area and not from an interaction with optical fields in the cavity. This conclusion is supported by the results of theoretical simulations by Nakwaski [2]. His modeling results in distributions of the current density inside the carrier confinement region show distinct maxima at the borders of the VCSEL and a deep dip in the center. Our modeling results also show the same behavior. These distributions are in good agreement with the experimental results of Degen et al. [1] and they favor strongly the emission of high order modes, which is due to inhomogeneous spatial gain distribution.

Multi Mode Behavior Due to Spatial Hole Burning:

The tendency to high order mode emission is further enhanced by spatial hole burning which is due to interaction between the optical field and the carrier reservoir in the cavity. The influence of these effects on the carrier distribution and on the lasing near-field have been modeled in detail by Zhao et al. [3] and by Kakwaski et al. [4]. The influence of spatial hole burning is much smaller than the effect of current spreading but it further enhances the tendency to higher order mode emission [3] [4].

Multi Mode Behavior Due to Strong Thermal Gradients Inside the Cavity:

A third effect that forces the laser to high order mode emission is the presence of strong thermal gradients in the cavity. These gradients have also been modeled by Nakwaski et al. [4] and temperature differences larger than 30K have been predicted between the center and the border region of the VCSEL. These differences originate from Joule-heating and heating by non-radiating recombination processes. Thus the temperature differences will be highest for injection currents larger than the thermal rollover point because the injection current is already high and non-radiating recombination is on the rise. As a consequence of this thermal gradient, carriers will be thermally excited and redistributed towards higher energies. This effect of spectral carrier redistribution is stronger in the hot center of the VCSEL and weaker at the cooler periphery. The strong redistribution of carriers in the center of the VCSEL obviously leads to a broad dip in the carrier distribution and eventually to a multi-mode spectrum.

The above effects have been well explained and experimentally demonstrated by several authors [1], [3], [4]. The effect of inhomogeneous carrier distribution is seen as the predominant mechanism towards governing the modal behavior in the cavity. There are some additional second order effects like diffusion of carriers in the active region and carrier recombination. The influence of these effects is assumed minimal in comparison to the effect due to inhomogeneous pump profile or carrier distribution.

Several prior address issues that the present invention is intended to address:

1. Jiang et al., U.S. Pat. No. 6,021,146 dated Feb. 2, 2001 uses the idea of heavy doping in the central region of the laser beam path to facilitate current confinement in the center suppressing overcrowding at the edge of the aperture. This approach involves a risk of degrading the active layer and increasing free carrier absorption, so the power output is limited.

2. Jiang et al., U.S. Pat. No. 6,026,111 dated Feb. 25, 2000 realizes single mode operation relies on the idea of using an extended cavity, which introduces high modal loss to high order laser modes while supporting the lower order modes. This approach suffers from low speed of the device as the cavity length is very long.

3. Anand Gopinath, U.S. Pat. No. 6,515,305 B2 dated Feb. 4, 2003 uses the idea of photonic band gap crystal fabrication on the top of the VCSEL. This promotes mode confinement by index guiding. This approach involves complex processing steps which adds to the cost, limits the active size of the device and eventually limits the output single-mode power.

There is a need, therefore, for a single mode semiconductor laser device that addresses the problems of multiple high order traverse modes and the limitation of higher single mode power and does so without reducing speed or size and without driving fabrication costs high.

### REFERENCES

[1] C. Degen, W. Elsaber and I. Fischer, “Transverse modes in oxide confined VCSELs: Influence of pump profile, spatial hole burning, and thermal effects,” Opt. Express 5, 38-47 (1999), http://www.opticsexpress.org/abstract.cfm?URI=OPEX-5-3-38.
[2] W. Nakwaski, “Current spreading and series resistance of proton-implanted vertical-cavity top-surface-emitting lasers,” Appl. Phys. A 61, 123-127 (1995).
[3] Y. G. Zhao and J. McInerny, “Transverse-Mode Control of Vertical-Cavity Surface-Emitting Lasers,” IEEE J. Quantum Electron. 32, 1950-1958 (1996).
[4] W. Nakwaski and R. P. Sarzala, “Transverse modes in gain-guided vertical-cavity surface-emitting lasers,” Opt. Commun. 148, 63-69 (1998).

### SUMMARY OF THE INVENTION

In the approach according to this invention modal behavior in the cavity of a semiconductor laser device is controlled both at higher injection and higher temperature by profiling the spatial current distribution and by a robust thermal management scheme. It relies on engineering the spatial distribution of the injection current profile by using multiple oxide apertures of varying size and varying distance from the active layer.

Objects of the invention, then, are, as compared to the prior art, simpler device design and growth, simpler device processing, better yield, lower cost and better performance of the laser.

Features of the mode controlled VCSEL in accordance with a preferred exemplary embodiment of this invention include one or more of:

a. Multiple oxide apertures to provide controlled spatial carrier distribution;

b. Preferred relative placement of the apertures to optimize the spatial carrier distribution;

c. Preferred relative size of the apertures to optimize the spatial carrier distribution; and

d. Tailoring of the doping profile of the DBR mirror with multiple oxide apertures to optimize the carrier distribution for large size devices.

The VCSEL of the preferred embodiment of the invention uses a minimum of two oxide apertures with different sizes and locations to tailor the current injection profile to match the fundamental mode of the optical field distribution profile. As gain is a logarithmic function of the injection current spatial distribution J(y), the bell-shape or near-Gaussian shaped spatial current distribution will help sustain only near-Gaussian fundamental mode in the cavity, barring or suppressing other higher order modes. Using two optimally placed apertures in the device, the spatial distribution of the current can be tailored to offset the detrimental effect of spatial hole burning. In a preliminary model the second order effects like diffusion, carrier recombination and existing optical field in the cavity are neglected.

High current density, single mode VCSELs in accordance with this invention are accomplished by:

1. The use of multiple apertures of varying size either by lateral oxidation technique or ion implantation, or a combination thereof, in VCSEL or edge emitting devices to suppress transverse modes.

2. The use of multiple apertures at optimized locations in the device so as to tailor the shape of the spatial distribution of the carriers in the active region.

3. The use of multiple apertures along with some on-wafer heat management schemes, namely a) electroplated via hole or b) epitaxial lift off and heat sink placement to produce high power in the device.

While developed particularly for a VCSEL, the above features can be used in many other opto-electronic devices, to name a few, FP edge emitting laser, DFB and DBR lasers, horizontal cavity surface-emitting lasers and, last but not least, quantum cascade lasers.

In comparison to the prior patents discussed above, our use of multiple apertures with varying size offers a very robust technique for single mode high power VCSELs. It does not add any complexity to either growth or processing. The different size of the apertures can be realized several ways, i.e. self-aligned mesa process, simple intracavity device processing or growing different concentration of Al mode fraction in the oxide layers, all well-known fabrication techniques.

The above and further objects and advantages of the invention will be better understood from the following detailed description of at least one preferred embodiment of the invention, taken in consideration with the accompanying drawings.

### BRIEF DESCRIPTION OF THE DRAWINGS

FIG. 1 is a diagrammatic illustration of a VCSEL configured in accordance with the present invention;

FIG. 2 is a plot of current density vs. distance from cavity center for a particular VCSEL of conventional design;

FIG. 3 is a graphical illustration of three plots of current density vs. distance from cavity center for three locations in a preferred embodiment of the VCSEL of the invention with the structure of FIG. 1;

FIG. 4 is a graphical illustration of current density and contour of current across a VCSEL in accordance with the invention;

FIG. 5 is a graphical illustration of three plots of current density vs. distance from cavity center for three locations in a further, preferred embodiment of the VCSEL of the invention with the structure of FIG. 1;

FIG. 6 is a diagrammatic illustration of a VCSEL configured in accordance with the invention and shows gold plating for heat removal;

FIG. 6A is a diagrammatic illustration like FIG. 6 of a further embodiment of the invention employing a heat sink for heat removal;

FIG. 7 is a plot of LIV characteristics of a VCSEL configured in accordance with the invention;

FIG. 8 is a plot of LIV characteristics of a VCSEL configured in accordance with the invention and showing the effect of gold plating for heat removal;

FIG. 9 is a plot of LIV characteristics of another VCSEL embodiment configured in accordance with the invention and having differing aperture locations and doping; and

FIG. 10 is a plot of spectra of a VCSEL configured in accordance with this invention with apertures located as in the VCSEL of FIG. 9 and at various injection currents.

### DETAILED DESCRIPTION

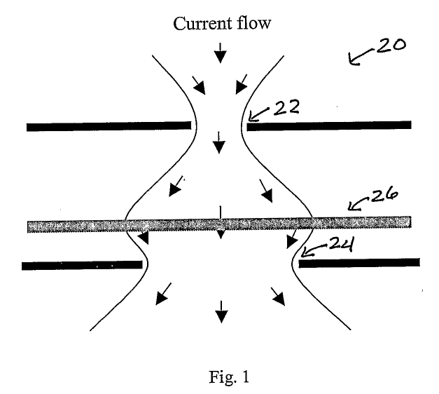

A schematic diagram of the location of a pair of apertures in accordance with the invention is shown in FIG. 1. In a VCSEL construction 20, at least two oxide apertures 22 and 24 with different sizes are located on each side of an active region 26 at varying distances from the active region in the DBRs or mirror stacks on each side of the active region. Current confinement and spreading in the cavity is controlled by the size and position of the oxide apertures. The current distribution strongly favors single mode operation if the size and distance of the apertures from the active region are optimally chosen. Since the mirror stacks are built up in pairs of mirrors as is known in DBR creation, distances of the oxide layers and oxide apertures from the active region are measured here and referred to here in “mirror pairs.”

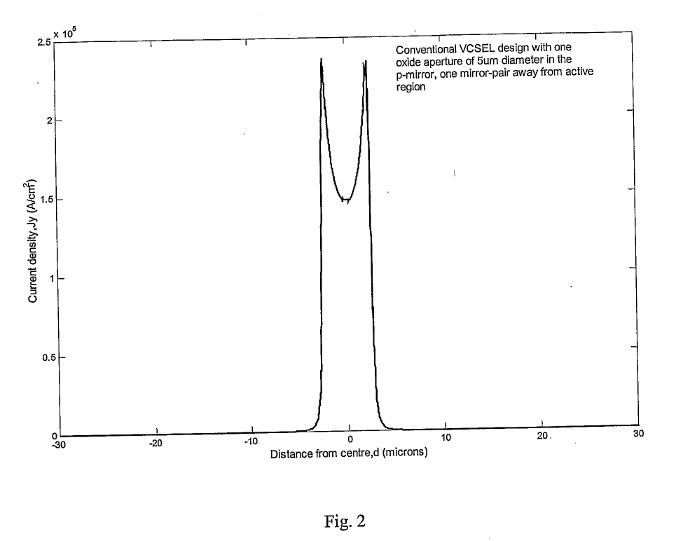

Detailed 3D modeling was carried out using Femlab, a popular finite element tool, to see the effect of double oxide-aperture in profiling the spatial carrier distribution. FIG. 2 shows the theoretical modeling results for a conventional VCSEL design, where the oxide layer is at the first null of the E-field in the p-mirror stack, which is placed roughly one mirror pair away from the cavity or active region between mirror stacks. In the conventional VCSEL design, workers in the art tend to place the oxide layer as close as the first null of the E-field to favor index guiding by the oxide layer and enhance current confinement in the active area. At smaller aperture and smaller injection, optical wave guiding effect becomes dominant thereby supporting single mode. From FIG. 2 it is clearly seen that the current distribution is not in favor of single mode operation despite the help of index-guiding effect because the carrier distribution has distinct maxima on the periphery of the aperture area. Therefore this conventional structure design can only support single mode operation at smaller aperture at around ˜5 μm, resulting in a very small output power, 1-2 mW.

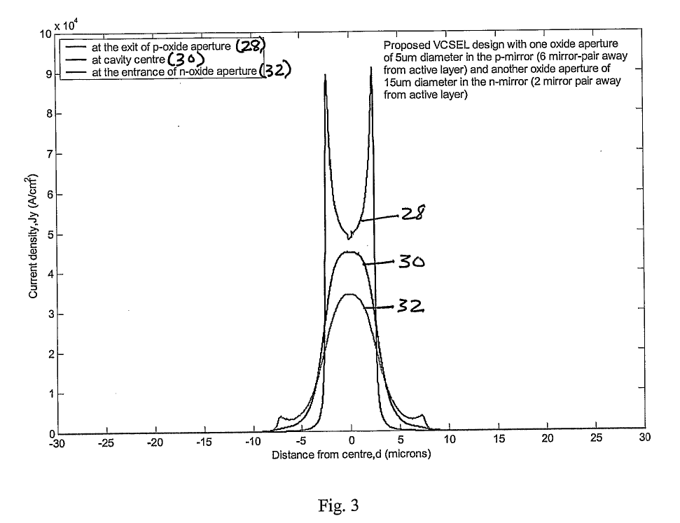

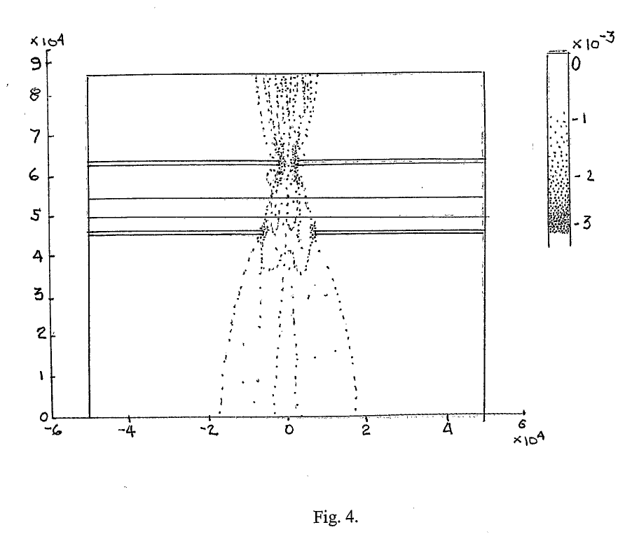

FIG. 3 shows one of the many optimal designs of VCSEL modeled by us which uses two oxide apertures placed relatively at suitable positions so that carriers are funneled and spread in a controlled manner so as to induce a near-Gaussian shape of spatial current density. In this particular design, the p-mirror oxide aperture (which is to say the oxide aperture on the p-mirror stack side of the active region) is six mirror pairs away from the cavity or active region and has a diameter of 5 μm and the n-mirror aperture (i.e. the oxide aperture on the n-mirror stack side of the active region) is two mirror pairs away from the cavity or active region and has a diameter of 15 μm. The curve 28 gives the current density at the cavity center. The curve 30 gives the current density at the p-oxide aperture and the curve 32 gives the current density at the entrance of the n-oxide aperture. FIG. 4 shows surface current density and contour line in this design. This optimum position and size is also a function of doping density in the epi-layers in the mirror stacks.

Here are a few observations from the preliminary modeling results:

1. For each set of relative size of oxide apertures (which decides the active-device size) there is an optimum relative position which gives near-Gaussian shaped spatial current density.

2. For each relative position of the oxide layers there is an optimum set of relative sizes of the apertures.

3. By adjusting the doping, the shape of the optimum spatial current distribution can be fine-tuned.

The above-mentioned mode control can be employed also in edge emitting Fabry Perot, DFB and DBR lasers.

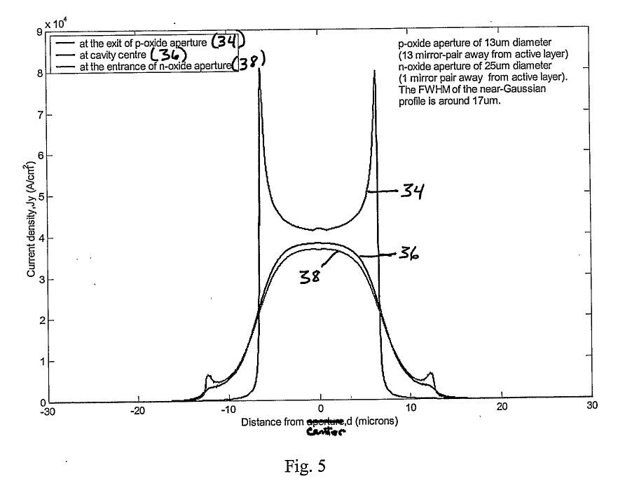

In FIG. 5 an optimum design has been modeled for a fairly large size device. The device size is around 17 microns. The current density shows a near-Gaussian profile. The curve 36 is the spatial current distribution in the active region. Curve 34 is the spatial current distribution at the exit of the p-oxide aperture. And curve 38 is the spatial current distribution at the entrance of the n-oxide aperture. The p-oxide aperture is 13 μm in diameter and is 13 mirror pairs away from the cavity or active region. The n-oxide aperture is 25 μm in diameter and is one mirror pair away from the cavity or active region.

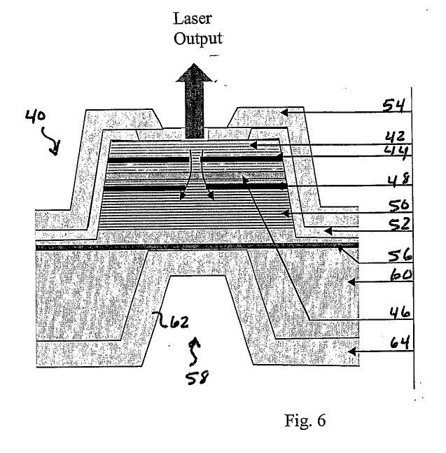

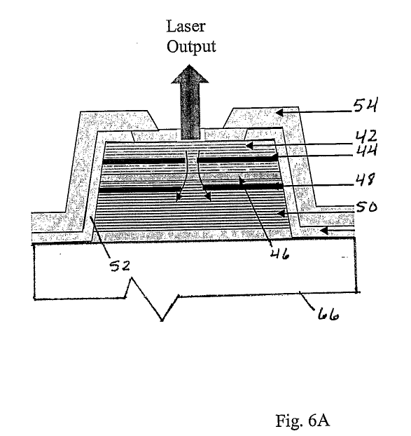

In FIG. 6, an exemplary double aperture VCSEL 40 is shown that is made in accordance with features of this invention. A p-mirror stack 42 and a top oxide aperture 44 are located above (or on one side of) an active region or layer 46. A bottom aperture 48 and an n-mirror stack 50 are located below (or on the other side of) the active region or layer 46. Also shown are a nitride isolation layer 52 separating the above-mentioned features from an electroplated gold p-contact 54. An etch-stop layer 56 is shown limiting the etch that forms a via 58 that is into a lapped substrate 60 of approximately 100 μm on which the VCSEL is built. The via 58 is electroplated with gold at 62 that forms, as well, an n-contact 64.

To address the thermal effect on the VCSEL, several schemes have been proposed here. One way for VCSELs on-wafer thermal management is as shown in FIG. 6. That is to etch the deep via 58 through the substrate 60 and electroplate the back and front sides of the wafer with thick gold 54, 62 and 64 to disperse the heat and bring down the junction temperature.

Another way to disperse heat is to lift off the layers of the device from the substrate and bond those layers onto and in good heat conducting relation to a heat sink substrate 66 of either thermally conductive metal or ceramic. This is depicted in FIG. 6A.

Experimental Results

Based on the concepts of this invention several 1050 nm VCSEL wafers were grown using MBE and fabricated into devices. Test results are here shown as the proof of concept.

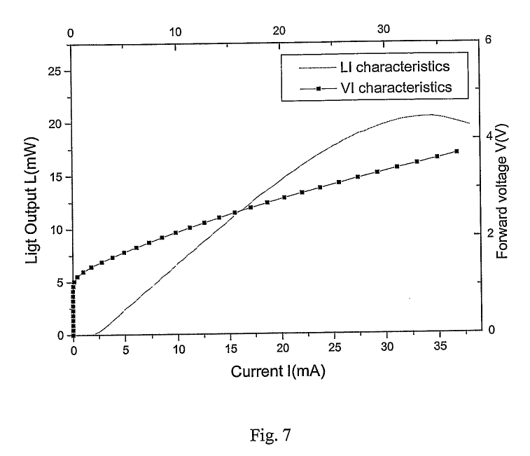

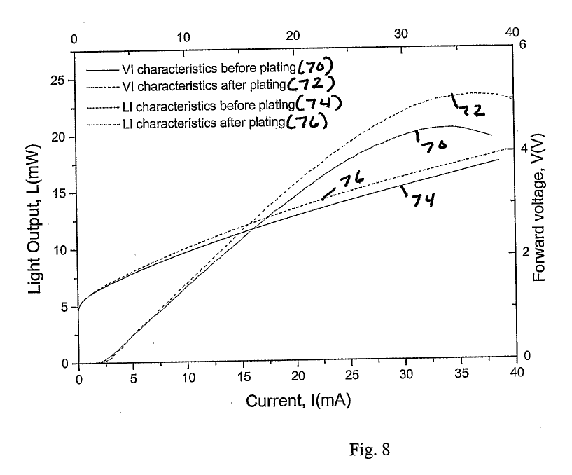

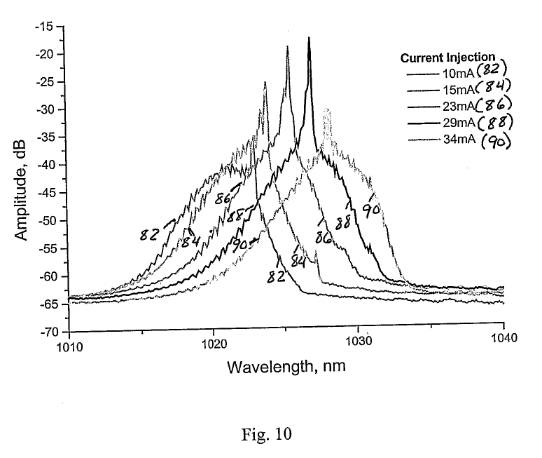

FIG. 7 shows LIV characteristics of a double aperture VCSEL with 17-micron p-aperture and 27-micron n-aperture. The peak power is more than 20 mW @ 33 mA. The peak wall plug efficiency is more than 30%. The threshold current is measured to be less than 2 mA and threshold voltage looks to be slightly above 1 volt. After around 6 micron thick gold electroplating there is an enhancement of peak power by nearly 15% as shown in FIG. 8. This VCSEL design has the p-aperture at third mirror pair in the p-mirror and n-aperture is on the first mirror pair in the n-mirror. As the p-aperture is not at the optimized position it shows an oxide peak in the spectrum. As a result the VCSEL is not single mode. However by moving the p-aperture farther away from the active region the spectral purity gets better as shown in FIG. 10.

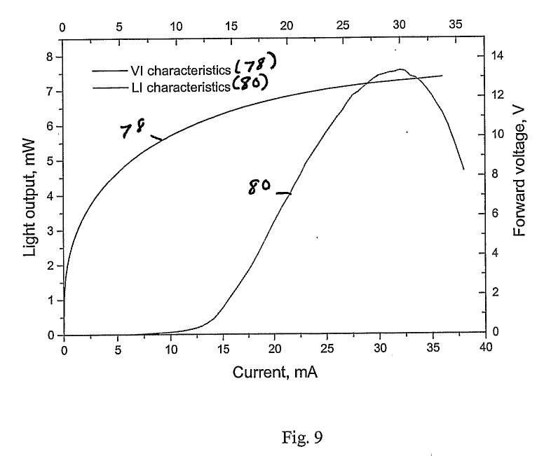

FIG. 9 shows the LIV characteristics of a double aperture VCSEL whose p-aperture is at the seventh mirror pair in p-DBR and n-aperture at the first mirror pair in n-DBR. The threshold current is more than 12 mA and threshold voltage is more than 7 volts. The record peak power is more than 7 mW at 12V. The higher threshold and lower peak power is due to the fact that for this growth the doping was lower by three times due to some problems in the MBE. FIG. 10 shows the spectrum of the VCSEL which reports single mode operation at the peak power and over the range of 20 mA current injection. This set of experiments has shown that invention is capable of tailoring the gain of a laser by tailoring the spatial current injection profile and thereby controlling the modal behavior of a VCSEL has been proved.

Although preferred embodiments of the invention have been described in detail, it will be readily appreciated by those skilled in the art that further modifications, alterations and additions to the invention embodiments disclosed may be made without departure from the spirit and scope of the invention as set forth in the appended claims.

We claim:

1. A semiconductor laser device including:
(a) a first oxide layer defining a first aperture;
(b) a second oxide layer defining a second aperture; and
(c) an active region located between the apertures;
the apertures being of sizes and distances from a center of the active region to induce a near-Gaussian shape of spatial current density distribution.

2. The laser device according to claim 1, having a p-mirror on one side of the active region and an n-mirror on another side of the active region, and wherein the first oxide layer is p-mirror oxide layer and the second oxide layer is an n-mirror oxide layer.

3. The laser device according to claim 2, wherein the first and second oxide layers and the first and second apertures defined differ in distance from the center of the active region.

4. The laser device according to claim 2, wherein the size of the first aperture is smaller than the size of the second aperture.

5. The laser device according to claim 3, wherein the size of the first aperture is smaller than the size of the second aperture.

6. The laser device according to claim 3, wherein each of the mirrors comprise stacks of mirror pairs, the first aperture is spaced at substantially three to twenty mirror pairs from the active region and the second aperture is spaced at substantially one to four mirror pairs from the active region.

7. The laser device according to claim 4, wherein each of the mirrors comprises stacks of mirror pairs, the first aperture is spaced at substantially three to twenty mirror pairs from the active region and the second aperture is spaced at substantially one to four mirror pairs from the active region.

8. The laser device according to claim 3, wherein the first aperture is substantially 3 to 20 μm across and the second aperture is substantially 5 to 30 μm across.

9. The laser device according to claim 4, wherein the first aperture is substantially 3 to 20 μm across and the second aperture is substantially 5 to 30 μm across.

10. The laser device according to claim 7, wherein the first aperture is substantially 3 to 20 μm across and the second aperture is substantially 5 to 30 μm across.

11. In a VCSEL having an active region, a first stack of mirror pairs on one side of the active region and a second stack of mirror pairs on a second side of the active region; the improvement comprising a first oxide aperture of a first size on the one side of the active region at a first distance from a center of the active region and a second oxide aperture of a second size on the second side of the active region at a second distance from the center of the active region.

12. The VCSEL according to claim 11, wherein the first aperture size differs from the second aperture size and the first distance differs from the second distance.

13. The VCSEL according to claim 12, wherein the first aperture size is smaller than the second aperture size and the first distance is greater than the second distance.

14. The VCSEL according to claim 13, wherein the first aperture size is substantially 5 to 30 μm across, the first distance is substantially 3 to 20 mirror pairs along the first mirror pair stack and the second distance is substantially one to four mirror pairs along the second mirror stack.

15. The VCSEL according to claim 11, further including a substrate upon which the active region and first and second mirror stacks are grown, a via into the substrate and into proximity with one of said mirror stacks, heat conductive plating extending from an outer surface into the via.

16. The VCSEL according to claim 14, further including a substrate upon which the active region and first and second mirror stacks are grown, a via into the substrate and into proximity with one of said mirror stacks, heat conductive plating extending from an outer surface into the via.

17. The VCSEL according to claim 11, further comprising a heat sink supporting the active region and the first and second mirror stacks, said heat sink extending into heat conducting relation to one of the mirror stacks.

18. The VCSEL according to claim 13, further comprising a heat sink supporting the active region and the first and second mirror stacks, said heat sink extending into heat conducting relation to one of the mirror stacks.
